(19) United States
(12) Patent Application Publication
(10) Pub. No.: US 2026/0079202 A1
(43) Pub. Date: Mar. 19, 2026

(54) ANALOG DIVIDER CIRCUITRY WITH BUILT-IN TEST CAPABILITY

(71) Applicant: Skyworks Solutions, Inc., Irvine, CA (US)

(72) Inventors: Kalyana Chakravarthy Vullaganti, Austin, TX (US); James David Barnette, Austin, TX (US); Sanjeev Tannirkulam Chandrasekaran, Austin, TX (US); Raghunandan Kolar Ranganathan, Round Rock, TX (US)

(21) Appl. No.: 19/333,128

(22) Filed: Sep. 18, 2025

Related U.S. Application Data
(60) Provisional application No. 63/696,619, filed on Sep. 19, 2024.
(60) Provisional application No. 63/696,624, filed on Sep. 19, 2024.
(60) Provisional application No. 63/696,614, filed on Sep. 19, 2024.

(51) Int. Cl. G01R 31/3163

(52) U.S. Cl. CPC G01R 31/3163

(57) ABSTRACT

A divider circuit includes an analog divider circuit with pre-load circuitry configured to allow for a programmable starting value. The circuit is responsive, synchronous with a divider clock, to count from the starting value, and includes an observation bus that outputs a current count value of the analog divider circuit. The divider circuit further includes test clock logic configured, in a divider circuit test mode, to be responsive to a reference clock to output the divider clock to clock the analog divider circuit for a number of clock cycles corresponding to a programmable test clock length.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

The disclosed technology relates to testing high speed divider circuits used in timing circuitry.

### Description of Related Technology

Timing products such as clock synthesizer integrated circuits generate clock signals utilized by a wide variety of electronic products. A typical clock synthesizer includes phase locked loops (PLL) each supplied with a reference signal from a source such as a crystal oscillator. PLLs and other clock synthesizer components typically include divider circuits because they can be used to synthesize clocks of different frequencies by dividing down higher frequency clocks.

### SUMMARY

Because divider circuits can play a key role in the functionality of timing components, there is a need to confirm the proper operation of dividers and identify manufacturing defects during production testing. However, given the wide bit-width of many divider circuits, existing methods for testing divider circuits can be excessively time consuming.

This challenge is particularly acute where divider circuits are included in analog integrated circuits which are not typically equipped with dedicated boundary scan circuitry. Boundary scan circuitry can be designed according to the Joint Test Action Group (JTAG) specification, for example, and can provide for efficient testing of digital circuits. However, analog integrated circuits are generally not compatible with boundary scan circuitry because, among other reasons, analog dividers can include non-standard flip-flop circuits.

Certain embodiments herein address such challenges by providing on-chip systems, devices and methods for reducing the testing time associated with testing on-chip divider circuits. The on-chip dividers can be augmented with test-mode functionality enabling flip-flop observability. Readout functionality can enable efficient outputting of test results, including a broadcast readout mode that allows simultaneous configuration, test, and readout of multiple on-chip dividers in parallel.

In some aspects, the techniques described herein relate to a timing circuit including: an analog divider circuit including pre-load circuitry configured to allow for programming the analog divider circuit with a starting value, and responsive, synchronous with a divider clock, to count from the starting value, and the analog divider circuit further including an observation bus that outputs a current count value of the analog divider circuit; and test clock logic configured, in a divider circuit test mode, to be responsive to a reference clock to output the divider clock to clock the analog divider circuit for a number of clock cycles corresponding to a programmable test clock length.

In some aspects, the techniques described herein relate to a timing circuit wherein the analog divider circuit forms a part of a phase-locked loop.

In some aspects, the techniques described herein relate to a timing circuit wherein the analog divider circuit is a feedback divider of the phase-locked loop.

In some aspects, the techniques described herein relate to a timing circuit wherein the analog divider circuit includes a plurality of series-connected flip-flops.

In some aspects, the techniques described herein relate to a timing circuit wherein the analog divider circuit includes count-down functionality.

In some aspects, the techniques described herein relate to a timing circuit wherein the analog divider circuit further includes count-up functionality.

In some aspects, the techniques described herein relate to a timing circuit wherein the test clock logic is further responsive to a test enable signal to output the divider clock.

In some aspects, the techniques described herein relate to a timing circuit wherein the analog divider circuit resides on an analog portion of a mixed-signal integrated circuit die, and the test enable signal is generated by a processing circuitry residing on a digital portion of the mixed-signal integrated circuit die.

In some aspects, the techniques described herein relate to a timing circuit wherein the reference clock is provided by a voltage controlled oscillator.

In some aspects, the techniques described herein relate to a timing circuit wherein the test clock logic resides in an interpolative divider.

In some aspects, the techniques described herein relate to a timing system including: at least one timing circuit having a first divider circuit including pre-load circuitry configured to allow for programming the first divider circuit with a starting value, and the first divider circuit responsive, synchronous with a divider clock, to count from the starting value, and the first divider circuit further including an observation bus that outputs a current count value of the first divider circuit, the at least one timing circuit further including test clock logic configured, in a divider circuit test mode, to be responsive to a reference clock to output the divider clock to clock the first divider circuit for a number of clock cycles corresponding to a programmable test clock length.

In some aspects, the techniques described herein relate to a timing system wherein the at least one timing circuit further a second divider circuit, the timing system including control circuitry configured to control the first divider circuit to perform a first test routine and to control the second divider circuit to perform a second test routine at least partially in parallel with the first test routine.

In some aspects, the techniques described herein relate to a timing system wherein the control circuitry is further configured to read the current count value from the observation bus of the first divider circuit as a first test result of the first test routine and to read the current count value from the observation bus of the second divider circuit as a second test result of the second test routine.

In some aspects, the techniques described herein relate to a timing system wherein the observation bus of the first divider circuit outputs the first test result at least partially in parallel with the observation bus of the second divider circuit outputting the second test result.

In some aspects, the techniques described herein relate to a timing system wherein the first divider circuit and the second divider circuit each include a respective serializer circuit configured to serialize the first test result and the second test result.

In some aspects, the techniques described herein relate to a timing system wherein the first divider circuit forms a part of a phase-locked loop.

In some aspects, the techniques described herein relate to a timing system wherein the first divider circuit is a feedback divider of the phase-locked loop.

In some aspects, the techniques described herein relate to a timing system wherein the first divider circuit includes a plurality of series-connected flip-flops.

In some aspects, the techniques described herein relate to a timing system wherein the first divider circuit includes count-down functionality.

In some aspects, the techniques described herein relate to a timing system wherein the first divider circuit further includes count-up functionality.

In some aspects, the techniques described herein relate to a timing system wherein the test clock logic is further responsive to a test enable signal to output the divider clock.

In some aspects, the techniques described herein relate to a timing system wherein the first divider circuit resides on an analog portion of a mixed-signal integrated circuit die, and the test enable signal is generated by a processing circuitry residing on a digital portion of the mixed-signal integrated circuit die.

In some aspects, the techniques described herein relate to a timing system wherein the reference clock is provided by a voltage controlled oscillator.

In some aspects, the techniques described herein relate to a timing system wherein the test clock logic resides in an interpolative divider.

In some aspects, the techniques described herein relate to a timing system wherein the first divider circuit includes an analog divider.

In some aspects, the techniques described herein relate to a method of testing divider circuitry, the method including: configuring at least one divider circuit in a test mode; pre-loading the at least one divider circuit with a first count value; clocking the at least one divider circuit for a first predetermined number of clock cycles; after clocking the at least one divider circuit for the first predetermined number of clock cycles, reading a first output value of the at least one divider circuit; and if the first output value meets a first predetermined criteria, determining with processing circuitry that the at least one divider circuit has passed a first test.

In some aspects, the techniques described herein relate to a method wherein the first test indicates whether one or more flip-flop circuits in the at least one divider circuit properly transition from outputting a low logic value to outputting a high logic value.

In some aspects, the techniques described herein relate to a method wherein the first output value is a maximum count value of the at least one divider circuit.

In some aspects, the techniques described herein relate to a method, further including: pre-loading the at least one divider circuit with a second count value; clocking the at least one divider circuit for a second predetermined number of clock cycles; after clocking the at least one divider circuit for the second predetermined number of clock cycles, reading a second output value of the at least one divider circuit; if the second output value meets a second predetermined criteria, determining that the at least one divider circuit has passed a second test.

In some aspects, the techniques described herein relate to a method wherein the first test determines whether one or more flip-flops of a plurality of flip-flops in the at least one divider circuit properly transition from outputting a low logic value to outputting a high logic value and the second test determines whether one or more of the plurality of flip-flops properly transition from outputting a high logic value to a low logic value.

In some aspects, the techniques described herein relate to a method wherein the first test determines whether all of the flip-flops of the plurality of flip-flops properly transition from outputting a low logic value to outputting a high logic value and the second test determines whether a single flip-flop of the plurality of flip-flops in the at least one divider circuit properly transitions from outputting a high logic value to a low logic value.

In some aspects, the techniques described herein relate to a method wherein reading the first output value includes outputting the first output value on a parallel bus, serializing the first output value, and communicating the first output value serially to digital processing circuitry.

In some aspects, the techniques described herein relate to a method wherein the at least one divider circuit includes a plurality of divider circuits, and the reading the first output value includes reading the first output value of each of the plurality of divider circuits in parallel with reading the first output value of the other divider circuits of the plurality of divider circuits.

In some aspects, the techniques described herein relate to a method wherein the first predetermined number of clock cycles is one.

In some aspects, the techniques described herein relate to a method wherein the first predetermined number of clock cycles is greater than one.

In some aspects, the techniques described herein relate to a method wherein the at least one divider circuit is a count-down divider.

In some aspects, the techniques described herein relate to a timing system including: at least one divider circuit including pre-load circuitry and output circuitry; divider test logic configured, in a divider test mode: to cause the pre-load circuitry to set the at least one divider circuit with a first initial count value; to clock the at least one divider circuit for a first predetermined number of clock cycles; after clocking the at least one divider circuit for the first predetermined number of clock cycles, to read a first output value of the at least one divider circuit via the output circuitry; and, if the first output value meets a first predetermined criteria, determine that the at least one divider circuit has passed a first test.

In some aspects, the techniques described herein relate to a timing system wherein the first test indicates whether one or more flip-flops of the at least one divider circuit properly transition from outputting a low logic value to outputting a high logic value.

In some aspects, the techniques described herein relate to a timing system wherein the first output value is a maximum count value of the at least one divider circuit.

In some aspects, the techniques described herein relate to a timing system wherein the divider test logic is further configured to cause the pre-load circuitry to set the at least one divider circuit to a second initial count value; clock the at least one divider circuit for a second predetermined number of clock cycles; after clocking the at least one divider circuit for the second predetermined number of clock cycles, read a second output value of the at least one divider circuit via the output circuitry; and, if the second output value meets a second predetermined criteria, determine that the at least one divider circuit has passed a second test.

In some aspects, the techniques described herein relate to a timing system wherein the first test determines whether one or more flip-flops of a plurality of flip-flops in the at least one divider circuit properly transition from outputting a low logic value to outputting a high logic value and the second test determines whether one or more of the plurality of flip-flops properly transition from outputting a high logic value to a low logic value.

In some aspects, the techniques described herein relate to a timing system wherein the first test determines whether all of the plurality of flip-flops properly transition from outputting a low logic value to outputting a high logic value and the second test determines whether a single flip-flop of the plurality of flip-flops in the at least one divider circuit properly transitions from outputting a high logic value to a low logic value.

In some aspects, the techniques described herein relate to a timing system wherein the output circuitry includes a parallel bus, and the timing system further includes a serializer circuit configured to serialize the first output value after the first output value is read via the output circuitry.

In some aspects, the techniques described herein relate to a timing system wherein the at least one divider circuit includes a plurality of divider circuits, each respective divider circuit of the plurality of divider circuits configured to output the first output value via the output circuitry of the respective divider circuit in parallel with the other divider circuits of the plurality of divider circuits.

In some aspects, the techniques described herein relate to a timing system wherein the first predetermined number of clock cycles is one.

In some aspects, the techniques described herein relate to a timing system wherein the first predetermined number of clock cycles is greater than one.

In some aspects, the techniques described herein relate to a timing system wherein the at least one divider circuit is a count-down divider.

In some aspects, the techniques described herein relate to a timing system wherein the at least one divider circuit is a count-down divider.

In some aspects, the techniques described herein relate to a mixed signal integrated circuit including: an analog portion including at least one divider circuit including pre-load circuitry and output circuitry; a digital portion including divider test logic configured, in a divider test mode: to cause the pre-load circuitry to set the at least one divider circuit with a first initial count value; to cause clocking of the at least one divider circuit for a first predetermined number of clock cycles; after clocking the at least one divider circuit for the first predetermined number of clock cycles, to cause reading a first output value of the at least one divider circuit via the output circuitry; and, if the first output value meets a first predetermined criteria, to determine that the at least one divider circuit has passed a first test.

In some aspects, the techniques described herein relate to a mixed signal integrated circuit wherein the divider test logic causes the clocking of the at least one divider circuit at least in part by communicating a control signal to divider clock circuitry residing in the analog portion.

In some aspects, the techniques described herein relate to a mixed signal integrated circuit wherein the divider test logic causes the reading of the first output value at least in part by controlling a serializer circuit coupled to the output circuitry of the at least one divider circuit.

In some aspects, the techniques described herein relate to a mixed signal integrated circuit wherein the analog portion and the digital portion reside on a common integrated circuit die.

In some aspects, the techniques described herein relate to a timing system including: a plurality of divider circuits, each divider circuit responsive, synchronous with a divider clock, to count from a start value, and each divider circuit further including an observation bus that outputs a test result; test control logic configured to control each divider circuit of the plurality of divider circuits to perform a test routine; and read circuitry configured to read test results output by each of the plurality of divider circuits in parallel with the other divider circuits of the plurality of divider circuits.

In some aspects, the techniques described herein relate to a timing system further including serializer circuitry configured to serialize the test results output by each of the plurality of divider circuits.

In some aspects, the techniques described herein relate to a timing system wherein further including digital logic that deserializes the test results for digital processing.

In some aspects, the techniques described herein relate to a timing system wherein, for each divider circuit of the plurality of divider circuits, the test routine includes clocking the divider circuit for a first predetermined number of clock cycles and then causing the read circuitry to read first test results output by each of the plurality of divider circuits in parallel.

In some aspects, the techniques described herein relate to a timing system wherein, for each divider circuit of the plurality of divider circuits, the test routine further includes, after causing the read circuitry to read the first test results, clocking the divider circuit for a second predetermined number of clock cycles and then causing the read circuitry to read second test results output by each of the plurality of divider circuits in parallel.

In some aspects, the techniques described herein relate to a timing system wherein the first test results indicate, for each divider circuit, whether one or more flip-flops of a plurality of flip-flops of the divider circuit properly transitioned from a low logic value to a high logic value, and the second test results indicate whether one or more flip-flops of the plurality of flip-flops properly transitioned from the high logic value to the low logic value.

In some aspects, the techniques described herein relate to a timing system wherein the first test results indicate, for each divider circuit, whether all of the flip-flops of the plurality of flip-flops properly transitioned from a low logic value to a high logic value, and the second test results indicate whether a single flip-flop of the plurality of flip-flops properly transitioned from the high logic value to the low logic value.

In some aspects, the techniques described herein relate to a timing system wherein each of the divider circuits further includes pre-load circuitry that allows for programming the divider circuit with the start value.

In some aspects, the techniques described herein relate to a timing system wherein the timing system includes at least one integrated circuit die, the plurality of divider circuits reside in an analog portion of the integrated circuit die, and the test control logic resides in a digital portion of the integrated circuit die.

In some aspects, the techniques described herein relate to a timing system further including, for each divider circuit of the plurality of divider circuits, test clock circuitry residing in the analog portion of the integrated circuit die configured to generate a test clock for clocking the divider circuit for a predetermined number of test clock cycles.

In some aspects, the techniques described herein relate to a method of testing a timing system, including: clocking each divider circuit of a plurality of divider circuits in the timing system with a divider clock to cause the divider circuit to count from a start value; with test control logic of the timing system, controlling the plurality of divider circuits to each perform a test routine; and with read circuitry of the timing system, reading test results output by each of the plurality of divider circuits in parallel with the other divider circuits of the plurality of divider circuits.

In some aspects, the techniques described herein relate to a method further including serializing the test results output by each of the plurality of divider circuits.

In some aspects, the techniques described herein relate to a method further including deserializing the serialized test results for digital processing.

In some aspects, the techniques described herein relate to a method wherein performance of the test routine includes, for each divider circuit of the plurality of divider circuits, clocking the divider circuit for a first predetermined number of clock cycles and then, with the read circuitry, reading first test results output by each of the plurality of divider circuits in parallel.

In some aspects, the techniques described herein relate to a method wherein performance of the test routine further includes clocking the divider circuit for a second predetermined number of clock cycles and then, with the read circuitry, reading second test results output by each of the plurality of divider circuits in parallel.

In some aspects, the techniques described herein relate to a method wherein the first test results indicate, for each divider circuit, whether one or more flip-flops of a plurality of flip-flops of the divider circuit properly transitioned from a low logic value to a high logic value, and the second test results indicate whether one or more flip-flops of the plurality of flip-flops properly transitioned from the high logic value to the low logic value.

In some aspects, the techniques described herein relate to a method wherein the first test results indicate, for each divider circuit, whether all of the flip-flops of the plurality of flip-flops properly transitioned from a low logic value to a high logic value, and the second test results indicate whether a single flip-flop of the plurality of flip-flops properly transitioned from the high logic value to the low logic value.

In some aspects, the techniques described herein relate to a method further including programming the plurality of divider circuits via pre-load circuitry of each divider circuit with the start value.

In some aspects, the techniques described herein relate to a method wherein the timing system includes at least one integrated circuit die, the plurality of divider circuits reside in an analog portion of the integrated circuit die, and the test control logic resides in a digital portion of the integrated circuit die.

In some aspects, the techniques described herein relate to a method further including test clock circuitry residing in the analog portion of the integrated circuit die configured to generate one or more test clocks for clocking each of the plurality of divider circuits for a programmable number of test clock cycles.

In some aspects, the techniques described herein relate to a timing product including: an analog portion including a plurality of divider circuits each responsive, synchronous with a divider clock, to count from a start value, and each further including an observation bus that outputs a test result, the analog portion further including read circuitry configured to read test results output by each of the plurality of the divider circuits in parallel with the other divider circuits of the plurality of divider circuits; and a digital portion including test control logic configured to control the plurality of divider circuits to each perform a test routine.

In some aspects, the techniques described herein relate to a timing product further including a mixed-signal integrated circuit including the analog portion and the digital portion.

### BRIEF DESCRIPTION OF THE DRAWINGS

Embodiments of this disclosure will now be described, by way of non-limiting example, with reference to the accompanying drawings.

FIG. 1 illustrates a phase-locked loop (PLL) that can be utilized by a clock synthesizer or other timing component, and which includes divider test functionality according to certain embodiments.

FIG. 2 illustrates an example of a clock synthesizer that includes a plurality of test-enabled dividers, according to certain embodiments.

FIGS. 3A-3B each illustrate a timing system including a plurality of test-enabled dividers, according to certain embodiments.

FIG. 4 is a flowchart depicting a method of performing automated testing of one or more test-enabled dividers according to certain embodiments.

FIG. 5 shows a timing diagram for a portion of a test routine for a test-enabled divider.

FIG. 6 shows a diagram of one example of a test-enabled analog divider circuit.

### DETAILED DESCRIPTION OF CERTAIN EMBODIMENTS

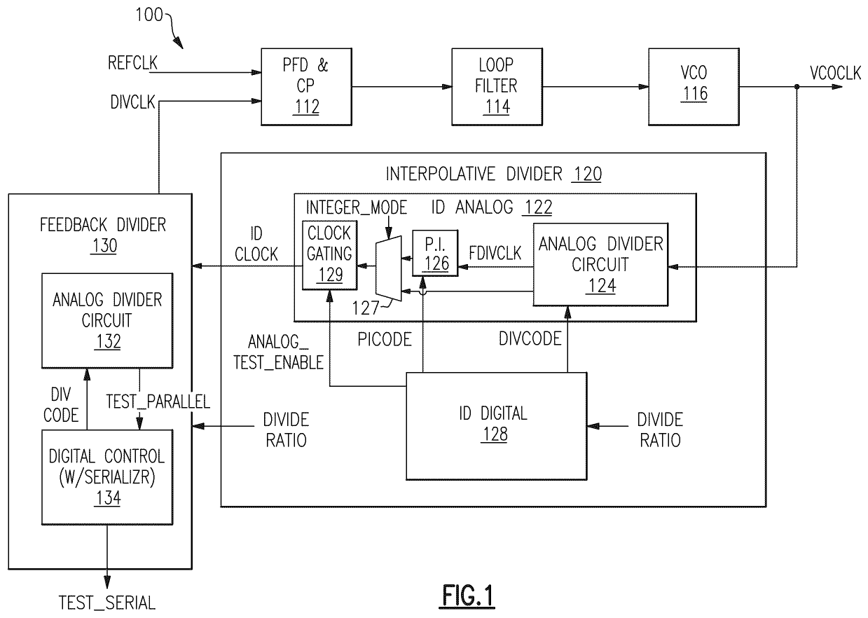

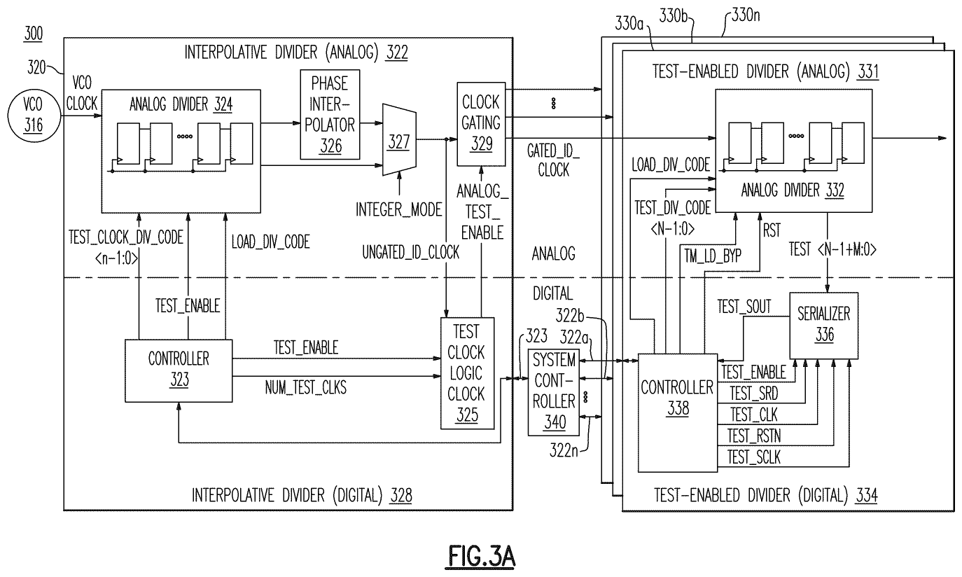

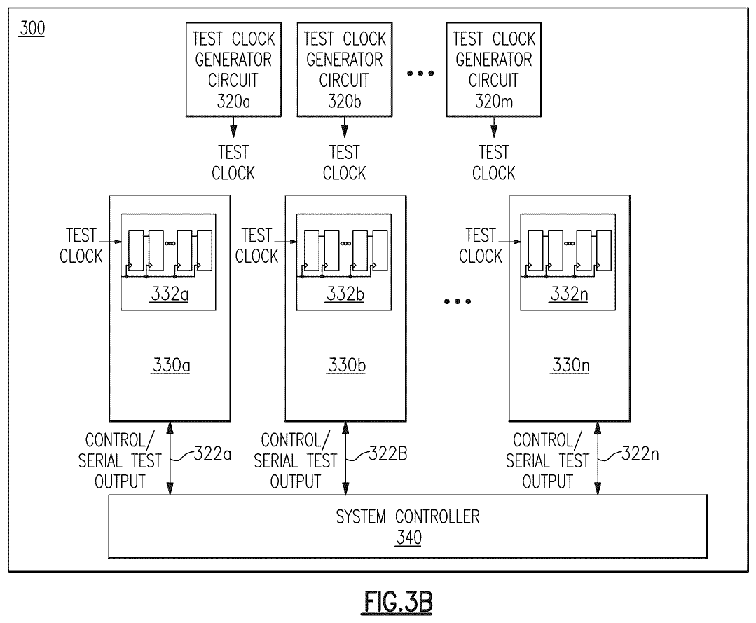

FIG. 1 illustrates a phase-locked loop (PLL) 100 that can be utilized by a clock synthesizer or other timing component. As will be explained in further detail, the PLL 100 can include any of the test mode functionality described herein, e.g., with respect to FIGS. 3A-6.

The PLL 100 includes a phase/frequency detector 112, a loop filter 114, a voltage-controlled oscillator (VCO) 116, an interpolative divider 120, and a feedback divider 130. As will be described, during a test mode of operation, the PLL 100 is configured to control the feedback divider 130 with a gated clock provided by the interpolative divider 120 to output a test value from the feedback divider 130.

During operation, the PLL 100 is supplied with a reference signal REFCLK from a source such as a crystal oscillator. Thus, during normal operation, a reference frequency of the REFCLK supplied to the PLL 100 is multiplied based on the divider value DIVCLK to generate the synthesized clock frequency. In at least one embodiment, DIVIDE RATIO is a digital frequency ratio translated from a code, e.g., a code provided by non-volatile memory.

The feedback divider 130 can supply the divided signal DIVCLK to phase/frequency detector 112 with noise associated with the nature of a fractional-N divider.

The voltage-controlled oscillator 116 may be implemented as a ring oscillator, an LC oscillator, or other suitable oscillator structure. The phase/frequency detector 112 receives the reference clock signal, REFCLK, which can be provided by a fixed source such as a crystal oscillator, a microelectromechanical structure (MEMS) oscillator, or other suitable source.

The interpolative divider 120 and the feedback divider 130 can include corresponding analog divider circuits 124, 132, which can be fractional-N dividers, for example.

The divider circuit 124 of the interpolative divider 120 can introduce a digital quantization error that causes phase noise (i.e., jitter) in the feedback clock signal FDIVCLK. For example, FDIVCLK may have jitter of up to one VCO clock cycle. The PLL 100 can reduce jitter by adjusting the phase of the frequency-divided signal according to a phase error control signal, PICODE. Interpolative divider techniques are described in U.S. Pat. No. 7,417,510, filed Oct. 17, 2006, entitled “Direct Digital Interpolative Synthesis,”, and U.S. Pat. No. 8,692,599, filed Aug. 22, 2012, entitled “Interpolative Divider Linearity Enhancement Techniques,” each of which patents are hereby incorporated by reference in their entirety.

The illustrated interpolative divider 120 includes an analog portion 122 that includes the fractional-N divider 124 and a phase interpolator 126. The illustrated feedback divider 130 includes an analog portion having the divider circuit 132. For example, the analog portions of the dividers 120, 130 can reside on in an analog domain of a mixed-signal integrated circuit having both analog and digital portions, or on a separate dedicated analog integrated circuit, depending on the embodiment. The phase interpolator 126 adjusts the phase of FDIVCLK according to the digital quantization error to reduce error in DIVCLK, thereby introducing a phase adjustment prior to phase/frequency detector 112 of PLL 100.

The interpolative divider 120 also includes a digital portion 128, which may comprise a typical first-order sigma-delta modulator. The digital module 128 generates the DIV_CODE for the fractional-N divider 124. In addition, the digital module 128 generates the PICODE and supplies it to phase interpolator 126. Phase interpolator 126 interpolates between the frequency-divided signal and one or more delayed versions of the frequency-divided signal (one or more equally spaced phases of the frequency-divided signal) based on the PICODE, which corresponds to the phase error. For example, phase interpolator 126 can generate multiple equally spaced phases of FDIVCLK and interpolate appropriate ones of those phases to generate DIVCLK.

The analog portion 122 of the interpolative divider 120 further includes a multiplexer 127 and a clock gating block 129. During normal (non-test mode) operation, the digital portion 128 of the interpolative divider 120 can control the multiplexer 127 to provide the output of the phase interpolator 126 to the clock gating block 129. During test mode, on the other hand, the digital portion 128 can control the multiplexer 127 to bypass the phase interpolator 127 and control the clock gating block 129 to provide a predetermined number of test clocks to the feedback divider 130, to thereby test the divider circuit 132 of the feedback divider 130. Moreover the feedback divider 130 additionally includes a digital control block 134, which during test mode operation can be configured to load the analog divider circuit 132 with an initial divide code (DIV_CODE), and output a test value (e.g., DIV_CODE−NUM_TST_CLKS) after the pre-determined number of test clocks (e.g., NUM_TST_CLKS) have elapsed. The digital control block 134 can additionally be configured to serialize the test value (e.g., DIV_CODE−NUM_TST_CLKS) for reading by the system to assess whether the divider circuit 132 is operating properly. Test mode operation will be described in further detail, e.g., with respect to FIGS. 3A-6.

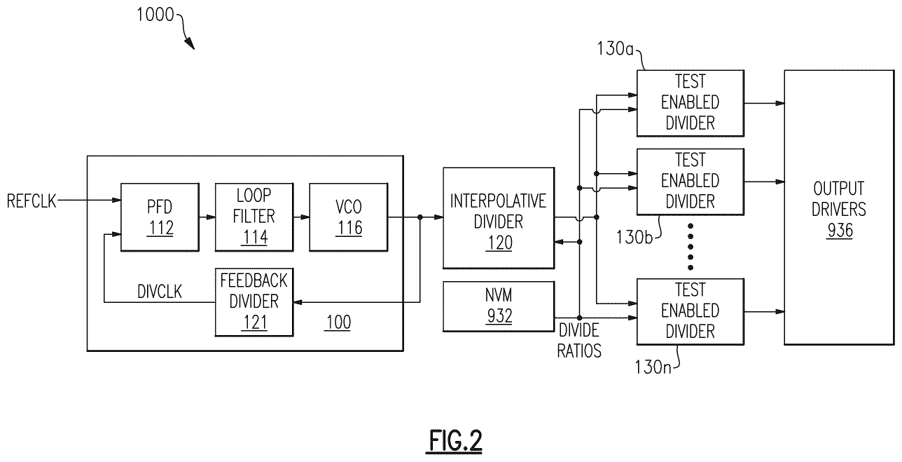

Referring now to FIG. 2, an exemplary clock synthesizer 1000 includes a PLL 100, which has phase/frequency detector 112, a loop filter 114, VCO 116, and a feedback divider 121. An interpolative divider 120, which can be similar to the interpolative divider of FIG. 1, receives the output of the VCO 116 and provides it to a plurality of test enabled output dividers 130a-130n. A storage device, such as the non-volatile memory 932 supplies DIVIDE RATIOS to the interpolative divider 120 and to the one or more output dividers 130a-130n.

The interpolative divider 120 and the one or more output dividers 130a-130n can be equipped with any of the test mode functionality disclosed herein, e.g., with respect to FIG. 1 or 3A-6. For instance, the interpolative divider 120 can be configured, like the interpolative divider 120 of FIG. 1, to output a predetermined number of test clocks in a test mode, for testing the output dividers 130a-130n. Each of the output dividers 130a-130n can include circuitry for pre-loading a test value (DIV_CODE) and a serializer for outputting serial test data in the test mode and circuitry for broadcasting the test data in parallel with the other output dividers. During normal operation, on the other hand, the output dividers 130a-130n can generate clock signals based on the output of VCO 116 (VCOCLK) and a corresponding fractional divider value received from the non-volatile memory 932. As shown, the integer divider 930 may also be included and receive a divide value from the non-volatile memory 932. Depending on the embodiment, the integer divider 930 can also be equipped with any of the test mode functionality disclosed herein. In some embodiments, the feedback divider 121 can also be equipped with any of the test mode functionality disclosed herein. output dividers 130a-130n respectively provide output clock signals to output drivers 936 of the clock synthesizer 1000.

FIG. 3A illustrates a timing system 300 including test mode functionality for confirming proper operation of a plurality of test-enabled dividers 330a-330n. In the illustrated embodiment, each test-enabled divider 330a-330n receives a gated output clock (GATED_ID_CLOCK) from an interpolative divider 320. Each test-enabled divider 330a-330n may be an output or feedback divider, for example. The illustrated timing system 300 may be a clock synthesizer implemented on a mixed signal integrated circuit configured to generate a plurality of programmable output clocks of different frequencies based on one or more input clock signals. Depending on the implementation, the timing system 300 may include additional functionality in addition to clock synthesis, such as network synchronization functionality (e.g., for the IEEE 1588 standard) or jitter attenuation.

The interpolative divider 320 and the test-enabled dividers 330a-330n may be used in a PLL of a clock synthesizer, for example, and may respectively be similar to or the same as the interpolative divider 120 and feedback divider 130 of the PLL 100 of FIG. 1. As another example, the interpolative divider 320 and the test-enabled dividers 330a-330n may respectively be similar to or the same as any of the any of the interpolative divider 120 and output dividers 130a-130n of FIG. 2.

While the illustrated system 300 includes a single interpolative divider 320 acting as a test clock generator for providing a test clock (GATED_ID_CLOCK) to each of the plurality of test-enabled dividers 330a-330n, other arrangements are possible where there are multiple test clock generators. For example, FIG. 3B shows a timing system 300 with m test clock generator circuits 320a-320m providing m test clocks to n test-enabled divider circuits 330a-330n. The test clock generator circuits 320a-320m can be interpolative dividers like the interpolative divider 320 of FIG. 3A, or some other type of test clock generator circuits each configured to output a predetermined number of test clock pulses to one or more of the divider circuits 330a-330n assigned to that clock generator circuit. For instance, in other configurations there can be a dedicated test clock generator circuit 320 for each of the divider circuits under test 330a-330n, where m=n. Or there can be a clock generator circuit for sub-groups of the dividers under test 330a-330n (e.g., for every 2, 4, 8, or 16 dividers under test). In some arrangements, different test clock generator circuits are provided based on the operational frequency of the dividers under test. For instance, there can be one or more first test clock generator circuits configured that output a test clock at a first frequency a first group of dividers under test, one or more second test clock generator circuits that output a test clock at a second frequency for a second group of dividers, and so on.

For simplicity of illustration, FIGS. 3A-3B show only certain relevant portions of the timing systems 300 to show certain componentry relevant to testing the dividers 330a-330n. However, it will be appreciated that the timing system 300 can include a variety of additional componentry not shown in FIG. 3A.

As delineated by the dashed line in FIG. 3A, the timing system 300 can include an analog domain including analog circuitry and a digital domain including digital circuitry. The analog domain and the digital domain reside on a common integrated circuit die in the illustrated embodiment, although in other implementations they can reside on separate dies.

The interpolative divider 320 includes analog portion 322 residing in the analog domain and a digital portion 328 residing in the digital domain. For example, the analog portion 322 of the illustrated interpolative divider 320 receives a VCO clock from a VCO 316, which may be similar to VCOs 116 of FIG. 1 or of FIG. 2. The analog portion 322 further includes a phase interpolator 326, which can be the same as the phase interpolator 126 of FIG. 1. A multiplexer 327 can, in response to a control signal (“integer-mode”), selectively provide a clock gating block 329 with either 1) the output of the phase interpolator 326 or 2) a divided clock directly from the analog divider 324. For example, during a test mode operation, the control signal can be set to a logic-high value to bypass the phase interpolator 326 and provide the divided clock directly from the analog divider 324 to the clock gating block 329, whereas during a normal operating mode, the control signal can be set to a logic-low value to provide the phase interpolated clock to the clock gating block 329.

The analog divider circuits 324 of the interpolative divider 322 and the analog divider circuit 332 of each test-enabled divider 330a-330n can each be an N-bit count-down divider, for example, including a plurality of series connected flip-flops and appropriate logic. The analog divider circuits 324, 332 may respectively be the same as the divider circuits 124, 132 of the interpolative divider 120 and the feedback divider 130 of FIG. 1, for example.

The timing system 300 may include any number of dividers including a variety of bit-widths, and can comprise some or all of feedback dividers, output dividers, input dividers, interpolative dividers, etc., of a clock synthesizer or other type of the timing system 300. In some implementations, the timing system 300 is a programmable clock synthesizer capable of generating multiple output clocks of various frequencies, and includes at least the following count-down divider circuits: 15 16-bit input dividers, 6 32-bit feedback dividers, 15 32-bit output dividers, 6 20-bit dividers, and 5 12-bit dividers, some or all of which can include the test functionality described herein.

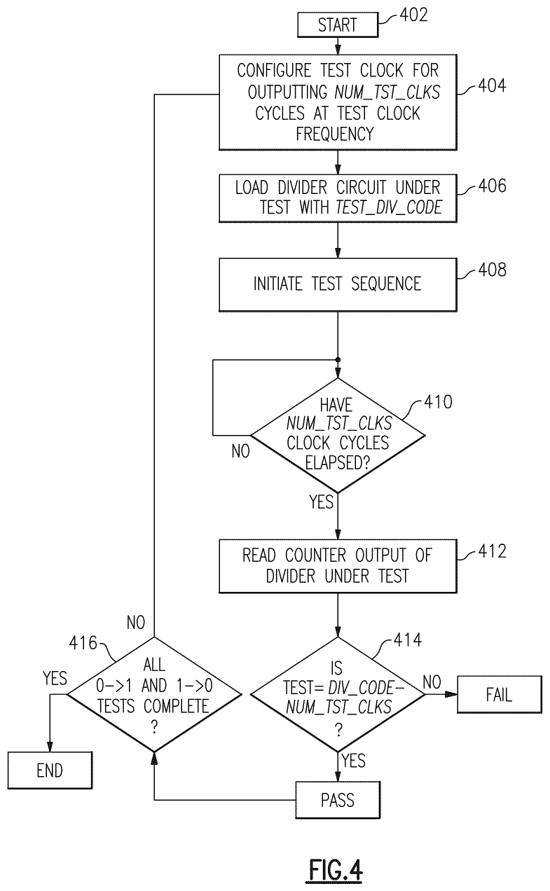

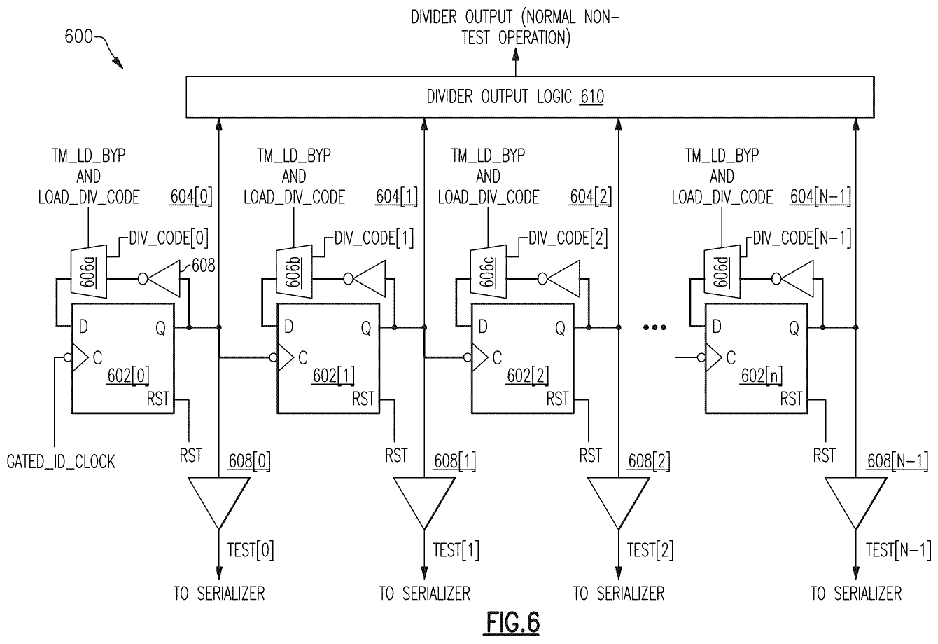

As will be described further, e.g., with respect to FIG. 4, the test-enabled dividers 330a-330n can be configured in a broadcast mode in which the timing system 300 can test the divider circuits 332a-332n of the dividers 330a-330n in parallel or at least partly in parallel and read test results from the dividers 330a-330n in parallel or at least partly in parallel, greatly reducing test time. For example, the test results of the dividers 330a-330n can be serialized by the serializer 336 of each respective divider 330 and the serial value can be output in parallel to the system controller 340 via the bus 322a-322n of the respective divider 330. FIG. 6, which will be described in further detail, shows one example of a compatible divider circuit 600 according to certain embodiments.

Referring again to FIG. 3A, the digital portion 328 of the interpolative divider 320, which serves as a test clock generation circuit, includes a controller 323, which may comprise digital memory and digital logic or processing circuitry, and test clock logic 325, which can be implemented in custom hardware, such as a state machine implemented in an application specific integrated (ASIC), or can partially or wholly be implemented in a microprocessor in other embodiments. The controller 323 can be coupled to a system controller 340. In some embodiments, system controller 340 may be implemented on one or more different dies than the interpolative divider(s) 320 (or other test clock generation circuits) or the test-enabled dividers 330a-330n. In other implementations the system controller 340 is implemented on the same die as the interpolative divider(s) 320 (or other test clock generation circuits) and/or the test-enabled dividers 330a-330n.

The digital portion 334 of the test-enabled divider 330 likewise includes a controller 338, which may comprise digital memory and digital logic or processing circuitry, and a serializer circuit 336 for serializing a test output value bus TEST provided by the divider circuit 332.

According to certain embodiments, the test functionality of the timing system 300 allows the analog divider circuits 332a-332n of the test-enabled dividers 330a-330n to be tested “at speed”, which can be at the normal operating speed of the divider circuit 332 (e.g., somewhere between 1 gigahertz and 3 gigahertz), rather than at a lower speed for testing, thereby reducing test time. In some embodiments, the divider circuits 332a-332n of the test-enabled dividers 330a-330n may operate at frequencies of 3 gigahertz or below, and the interpolative divider(s) 322 (or other test clock generation circuits) operate at a frequency above 3 gigahertz.

### Test Methods

FIG. 4 is a flowchart 400 depicting a method of performing automated testing of one or more analog divider circuits according to certain embodiments. While the method will be described with respect to the timing systems 300 of FIGS. 3A-3B for the purposes of illustration, the method can be implemented by other compatible timing systems.

The method starts at operation block 402. For example, as part of a validation routine, a microprocessor or other processing circuitry of the system controller 340 can execute software or firmware for automated testing of the divider circuit(s) 332a-332n of each of the divider circuits under test 330a-330n.

Referring to FIG. 3A, as part of the testing process, the system level controller 340 may issue commands to controller 323 of the interpolative divider 320 via the control bus 323 for carrying out a validation routine for testing the divider circuit 332 of the test-enabled divider 330. While FIG. 4 will be described primarily in the context of a system such as the one of FIG. 3A, which includes a single interpolative divider 320 serving as a clock generation circuit for a plurality of divider circuits 330a-330n, it will be appreciated that more test clock generation circuits can be used to generate multiple test clocks, as explained previously.

### ‘0’ to ‘1’ Testing

At block 404, the system controller 340 may issue commands and data to the interpolative divider(s) 320 to provide NUM_TST_CLKS test clock pulses to one or more of the test-enabled dividers 330a-330n at a desired test clock frequency.

For instance, to test proper operation of each of the flip-flops in the divider circuit 332 of the test-enabled dividers 330a-330n in transitioning from a ‘0’ output value to a ‘1’, at block 404, the system level block 340 can send the following commands and data to controller 323 of the interpolative divider 320 for properly generating the test clock: 1) a value NUM_TST_CLKS indicating how many clock cycles should be issued to the divider circuit 332 of the test-enabled dividers 330a-330n during the test sequence, 2) a desired test clock frequency. In response, the controller 323 can: 1) control the multiplexer 327 to bypass the phase interpolator 326 and send the divided output of the divider circuit 324 directly to the clock gating circuit 329, 2) calculate a divide code value TEST_CLOCK_DIV_CODE corresponding to desired the test clock frequency and provide the value to the divider circuit 324, 3) assert the LOAD_DIV_CODE and TEST_ENABLE control signals to pre-load TEST_CLOCK_DIV_CODE the into the divider circuit 324, and 4) provide NUM_TST_CLKS to the test clock logic 325. In other implementations, instead of the controller 323 calculating the value of TEST_CLOCK_DIV_CODE based on the desired test clock frequency, the system controller 340 calculates the value provides it to the controller 323.

In one example scenario, the divider circuit 332 of a divider(s) under test is a 32-bit count-down divider circuit, and the validation routine specifies NUM_TST_CLKS=5. Thus, at block 404, the controller 323 provides a value of 5 to the test clock logic 325.

At block 406, the system level controller 340 may cause the divider circuit(s) under test 332a-332n to be pre-loaded with TEST_DIV_CODE. For example, the system level controller 340 can send the controller 338 of the test-enabled divider(s) 330a-330n a command to prepare the divider circuit 332 of each divider under test 330 for a 0->1 test, and the controller 338 can respond by: 1) determining a proper TEST_DIV_CODE for 0->1 testing and providing that value to divider circuit 332, and 2) asserting the LOAD_DIV_CODE, TM_LD_BYP, and RST signals to asynchronously pre-load the calculated TEST_DIV_CODE value into the divider circuit 332. For 0->1 transition testing, according to certain embodiments, the controller 338 can determine TEST_DIV_CODE according to the equation NUM_TST_CLKS−1.

In the example scenario where the divider circuit 332 is a 32-bit count-down divider circuit and NUM_TST_CLKS=5, the validation routine specifies a TEST_DIV_CODE of NUM_TST_CLKS-1=5−1=4. Thus, at block 406 the method includes obtaining the NUM_TST_CLKS value of 5, calculating a TEST_DIV_CODE of 4, and configuring the divider circuit 332 with that value. For instance, the controller 338 can respond to the command to load the TEST_DIV_CODE value by obtaining the NUM_TST_CLKS value of 5 from memory, calculating the TEST_DIV_CODE value of 4, outputting the calculated value on the 32-bit bus to the analog divider circuit 332, and asserting the LOAD_DIV_CODE, TM_LD_BYP, and RST control signals, thereby causing the analog divider circuit 332 to asynchronously reset and load a ‘1’ into the flip-flop representing the third least significant bit and a ‘0’ into the remaining flip-flops, corresponding to a pre-loaded binary value of 4. An example of pre-load circuitry will be described in connection with the divider circuit 600 FIG. 6. In other implementations, the TEST_DIV_CODE is not determined by the controller 338 and instead the system level controller 340 determines TEST_DIV_CODE and provides it to the controller 338.

At operation block 408, the method includes initiating a test sequence for the divider(s) 330a-330n under test. For example, the system 300 enters a test mode and initiates a programmed script or other sequence for testing the dividers 330a-330n. This causes the system controller 340 to command the controller 323 to activate the TEST_ENABLE control, which the test clock logic 325 responds to by activating the control signal ANALOG_TEST_ENABLE for an amount of time calibrated to cause the clock gating circuit 329 to output NUM_TST_CLKS clock pulses to the test-enabled divider 330. The test clock logic 325 can process both the UNGATED_ID_CLOCK provided by the multiplexer 327 and the TEST_ENABLE signal to generate ANALOG_TEST_ENABLE. In response to ANALOG_TEST_ENABLE, the clock gating circuit 329 can retime UNGATED_ID_CLOCK and perform a logical AND of the re-timed UNGATED_ID_CLOCK and ANALOG_TEST_ENABLE to generate NUM_TST_CLKS pulses of GATED_ID_CLOCK. Thus, as a result of the AND gating operation, the GATED_ID_CLOCK can be a copy of the re-timed UNGATED_ID_CLOCK so long as the ANALOG_TEST_ENABLE signal is logic-high. On the other hand, when ANALOG_TEST_ENABLE is log-low, GATED_ID_CLOCK can be inactive/logic-low.

Because the test control logic 325 is configured to hold the ANALOG_TEST_ENABLE signal active long enough for the clock gating block 329 to output NUM_TST_CLKS clock pulses, in the example scenario, the GATED_ID_CLOCK signal pulses for 5 clock cycles. In response, the analog divider circuit 332 under test will, during proper operation, count down by NUM_TST_CLKS from the pre-loaded TEST_DIV_CODE value. In the example scenario, the 32-bit divider circuit(s) 332 under test will count down as follows (in hexadecimal notation): 0000 0004 (before first GATED_ID_CLOCK)→0000 0003 (after the first GATED_ID_CLOCK)→0000 0002 (after the second GATED_ID_CLOCK)→0000 0001 (after the third GATED_ID_CLOCK)→0000 0000 (after the fourth GATED_ID_CLOCK)→ffff ffff (after the fifth GATED_ID_CLOCK). Thus, because the counter circuit 332 rolls over from 0000 0000 to the maximum value of ffff ffff after NUM_TST_CLKS clock cycles, every flip-flop in the divider circuit 332 will toggle from ‘0’ to ‘1’ after the completion of the test sequence and the fifth GATED_ID_CLOCK pulse, assuming proper operation and no manufacturing defects.

At block 410, the method queries after each clock cycle whether NUM_TST_CLKS clock cycles have elapsed. When NUM_TST_CLKS clock cycles have elapsed, the method at block 412 reads the output count value of the divider circuit(s) under test 332. The divider circuit(s) under test 332 can include one or more buffers or other observability circuitry to enable the current output of each flip-flop of the divider 332 to be output in parallel to the serializer 336. FIG. 6 shows an example of compatible observability circuitry.

At block 412, after determining at block 410 that NUM_TST_CLKS test clock cycles have elapsed, the system controller 340 or other appropriate entity can, for each divider under test 332, command the controller 338 to output values on the serial interface control bus connected between the controller 338 and the serializer 336 to command the serializer 336 to (1) read the N+M-bit parallel test value [N−1+M:0] provided by the observability circuitry of the analog divider circuit 306 and (2) sequentially output each of the N+M-bits on the TEST_SOUT serial bus connected between the serializer 336 and the controller 338. For instance, the illustrated serial interface control bus includes the TEST_ENABLE signal, a TEST_SRD signal, a TEST_CLK signal, a TEST_RST signal, and a TEST_SCLK signal. The TEST_ENABLE signal can be activated to cause the serializer 336 to load the test value into a memory buffer within the serializer 336, the TEST_SRD signal can be activated initiate the serial output of the test value from the memory buffer within the serializer 336 over the TEST_SOUT serial output, the TEST_CLK signal can provide a reference clock to the serializer 336, e.g., for clocking control circuitry within the serializer 336, the TEST_SCLK signal can be used as a serial clock for timing the serial output, and the TEST_RST signal can be activated to reset the serializer 336 (e.g., clearing the internal memory buffer) after the entire test value has been provided to the controller 338.

The test bus is N+M bits wide because M additional bits allow for testing of a zero-detect circuit within the divider circuit 332. In one implementation, M=4, although other values are possible.

After the test value for each of the divider(s) under test 330a-330n has been read into the respective controller 338, the method at block 414 determines, for each divider under test 330a-330n, whether the test [N−1:0] value read from the divider circuit 332a-332n equals TEST_DIV_CODE−NUM_TST_CLKS. If not, the method determines that the part has failed. If yes, the method determines that the part has passed the current test which, in the example scenario, is a 0->1 test confirming proper operation of the flip-flops in the divider circuit when transitioning from ‘0’ to ‘1’. For example, in the example scenario, after 5 test clocks, DIV_CODE−NUM_TST_CLKS=4−5=−1. Because the 32-bit divider under test is not configured to represent negative values, but instead rolls over from 0000 0000 to the maximum value ffff ffff, a test value of −1 corresponds to a count value of ffff ffff. Thus, assuming proper operation, a test value of ffff ffff at block 414 after 5 test clocks corresponds to a passing 0->1 transition test, indicating that all 32-bits transitioned from 0->1.

As will be appreciated, other values of NUM_TST_CLKS can be used. For example, in another example scenario, NUM_TST_CLKS is set to 1 and DIV_CODE is therefore set to NUM_TST_CLKS−1=1−1=0. In this case, the test output will transition from the initial DIV_CODE value of 0000 0000 to ffff ffff after a single pulse of the gated_ID_clock, and the 0->1 transition test completes after a single gated_ID_clock cycle.

### ‘1’ to ‘0’ Testing

If the test passes, then at block 416 the method determines whether all 0->1 and all 1->0 testing has been completed for all flip-flops in the divider circuit(s) under test 332.

In the example scenario, 0->1 transition testing is completed for all flip-flops, but not 1->0 transition testing, and thus at block 416 the method returns to block 404 to configure the divider(s) under test 330a-330n for 1->0 transition testing. For a count-down divider, multiple flip-flops do not transition from 1->0 simultaneously during normal operation, unlike for 0->1 transition testing, where all bits simultaneously change when the counter rolls from 0. Thus, to test each flip-flop for a proper 1->0 transition, the method can iterate multiple times, e.g., once for each flip-flop in each divider circuit under test 332.

Where the divider circuit 332 is an N-bit count-down divider, the method can include setting a DIV_CODE value for testing proper 1->0 transition of a flip flop corresponding to a bit in the divider circuit 332 after NUM_TST_CLKS clock cycles according to the following equation: DIV_CODE=2\hat{ }ⁱ+NUM_TST_CLKS, where i is the flip-flop, with i=0 being the flip-flop representing the least significant bit, and i=N−1 corresponding to the flip-flop representing the most significant bit.

For testing the flip-flop corresponding to the i-th flip flop of the analog divider circuit under test 332, at block 404 the system level controller 340 can send the test controller 323 of the interpolative divider 320 commands and data for properly generating the test clock as discussed above for 0->1 testing.

At block 406, the system level controller 340 causes the divider circuit(s) under test 332a-332n pre-load with TEST_DIV_CODE as described above for 0->1 testing. However, unlike for 0->1 testing, for 1->0 testing, a DIV_CODE value is calculated according to 2\hat{ }ⁱ+NUM_TST_CLKS−1, where i is the current flip-flip/bit under test. The table below shows DIV_CODE values for testing the 1->0 transition of each bit of a 32-bit count down divider for NUM_TST_CLKS values of 1 and 5.

| | DIV_CODE | DIV_CODE |
|---|---|---|
| Bit | (NUM_TST_CLKS = 1) | (NUM_TST_CLKS = 5) |
| 0 | 1 | 5 |
| 1 | 2 | 6 |
| 2 | 4 | 8 |
| 3 | 8 | 12 |
| 4 | 16 | 20 |
| 5 | 32 | 36 |
| 6 | 64 | 68 |
| 7 | 128 | 132 |
| 8 | 256 | 260 |
| 9 | 512 | 516 |
| 10 | 1024 | 1028 |
| . . . | . . . | . . . |
| 31 | 2,147,483,648 | 2,147,483,652 |

Thus, for a 32-bit count-down divider and a NUM_TST_CLKS value of 5, the validation routine executes 32 iterations of blocks 404-416, one for each bit in the analog divider circuit 332, each iteration having the DIV_CODE value listed in the righthand column in the table above for the corresponding bit i. Thus, during each iteration, the controller 338 pre-loads the divider circuit 332 by outputting the appropriate DIV_CODE value and asserting the LOAD_DIV_CODE, TM_LD_BYP, and RST control signals, thereby causing the divider circuit 332 to asynchronously pre-load the DIV_CODE value into the flip flops of the divider circuit under test 332.

In the example scenario, in the 32nd and final iteration of the 1->0 transition testing for the final bit (i=31), the gated_ID_clock signal can pulse for 5 clock cycles and in response, the divider circuit 332 will, during proper operation, count down by 5 (NUM_TST_CLKS) from 2,147,483,652 (DIV_CODE for i=31). During proper operation, the 32-bit divider circuit 306 will count down as follows (in hexadecimal notation): 8000 0004 (before the first gated_ID_clock)→8000 0003 (after the first gated_ID_clock)→8000 0002 (after the second gated_ID_clock)→8000 0001 (after the third gated_ID_clock)→8000 0000 (after the fourth gated_ID_clock)→7fff ffff (after the fifth gated_ID_clock). Thus, during proper operation, the most significant bit will have properly transitioned from 1->0 if, after the fifth clock pulse, the test value reads 7fff ffff. In other words, the most significant bit will have properly transitioned from 1->0 if at block 414 the method determines that (in hexadecimal notation) test=DIV_CODE−NUM_TST_CLKS=8000 0004−0000 0005=7fff ffff.

If all 32 iterations of blocks 404-414 result in a “PASS” at block 414, the method determines at block 416 that all 0->1 and 1->0 transition tests have completed, and the method ends, having confirmed that each of the flip-flops in the divider circuit(s) under test 332 have properly transitioned from 0->1 and 1->0.

The test techniques described herein can achieve dramatic test time reduction and corresponding cost savings. For instance, it has been found that the test time for a 32-bit count down divider clocked at 1.4 gigahertz can be reduced from 3.9 seconds per divider to 7.8 milliseconds.

While the example scenario describes testing of count-down divider circuits, in other embodiments, the divider circuit(s) under test 332 can be additionally or alternatively include count-up functionality. In such cases, where the divider circuit 332 is configured to count both down and up, the method can implement the 1->0 transition test differently than described above. In certain such cases, every flip-flop in the divider circuit 306 can be tested for 1->0 transition in a single iteration of blocks 404-414. For example, the DIV_CODE value can be set to the maximum counter value max_cnt_value−NUM_TST_CLKS+1. For a 32-bit counter with NUM_TST_CLKS set to 5, DIV_CODE=ffff ffff−0000 0005+0000 0001=ffff ffff−0000 0004=ffff fffb. During proper operation, the 32-bit divider circuit 306 will count up as follows (in hexadecimal notation): ffff fffb (before the first GATED_ID_CLOCK)→ffff fffc (after the first GATED_ID_CLOCK)→ffff fffd (after the second GATED_ID_CLOCK)→ffff fffe (after the third GATED_ID_CLOCK)→ffff ffff (after the fourth GATED_ID_CLOCK)→0000 0000 (after the fifth GATED_ID_CLOCK). Thus, because the counter circuit 332 rolls over from the maximum value ffff ffff to 0000 0000 after NUM_TST_CLKS clock cycles elapsed, during proper operation, every flip-flop in the divider circuit 332 should have toggled from ‘1’ to ‘0’ during the test sequence. As another example, if NUM_TST_CLKS=1 for a divider with count-up functionality, DIV_CODE=ffff ffff−0000 0001+0000 0001=ffff ffff−0000 0000=ffff ffff. Thus, after the single gated_ID_clock, the counter circuit 332 rolls over from the maximum value ffff ffff to 0000 0000, thereby allowing for testing of proper 1->0 transition of every flip-flop in the divider circuit 332 in a single clock cycle.

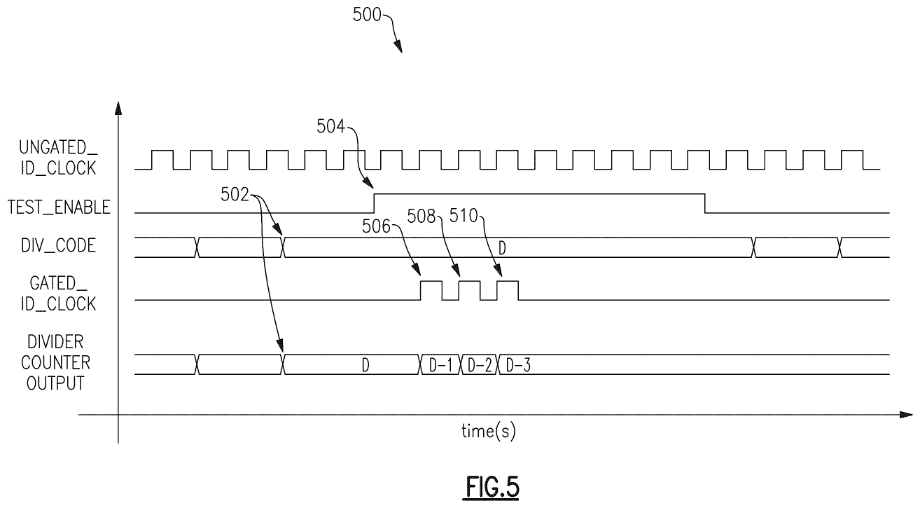

FIG. 5 shows a timing diagram 500 for a portion of a test cycle for a scenario where NUM_TST_CLKS is 3 and DIV_CODE is D. At time 502, a value of D is presented to the DIV_CODE input of the analog divider circuit under test 332, and each bit of the DIV_CODE value can be presented to an input of a corresponding flip-flop in the divider circuit 332. As shown, at time 502, or shortly thereafter, the divider counter output value D is also propagated to the TEST output of the divider circuit 332. For example, at time 502, LOAD_DIV_CODE, TM_LD_BYP, and RST are asserted, thereby asynchronously resetting each flip-flip in the divider circuit 332 and pre-loading the DIV_CODE value of D into the divider circuit 332. In this manner, at time 502 each bit of the binary representation of D is latched to an output of a corresponding flip-flop in the analog divider circuit 332. At time 504, the TEST_ENABLE control signal toggles from 0 to 1, causing the test clock logic 325 to activate the ANALOG_TEST_ENABLE control signal, which causes the clock gating circuit 329 to generate three pulses of the test clock GATED_ID_CLOCK at times 506, 508, 510. This causes the divider circuit 332 to decrement from D to D−1 at time 506, from D−1 to D−2 at time 508, and from D−2 to D−3 at time 510.

### Broadcast Test Readout

Returning to FIGS. 3A-3B again, according to certain embodiments, the timing system 300 can be configured for broadcast testing and readout in which the timing system 300 tests the analog divider circuits 332 of multiple dividers under test 330a-330n in parallel, simultaneously, and/or reads out the test values in parallel, simultaneously. Particularly where the timing system 300 includes a relatively large number of divider circuits 300 (e.g., 10, 20, 30, 40, 50, 100 or more), the broadcast test and read out functionality can further dramatically reduce overall testing time.

During broadcast test operation, the timing system 300 controls some or all of dividers under test 330a-330n in parallel in a fashion similar to that described herein, e.g., with respect to the method of FIG. 4. For instance, the system level block 340 can simultaneously broadcast instructions to some or all the dividers under test 330a-330n in parallel or in at least a partially overlapping fashion to cause the dividers 330a-330n to begin testing their respective analog divider circuit 332. The dividers under test 330a-330n respond by carrying out the testing operation described with respect to FIG. 4, in which the serializers 336 of the respective dividers 330a-330n serially output the test results to the respective controller 338. The respective controllers 338 of each divider under test 330a-330n can then forward the results to the system level block 340 via the respective serial buses 322a-322n. Similarly, the system level block 340 can simultaneously broadcast instructions to some or all the clock generation circuits, such as the interpolative dividers 320a-320m to generate m test clocks for the n dividers 330a-330n.

In alternative configurations, each divider under test 330a-330n does not have a separate dedicated serializer 336 and/or test controller 338. Instead, some or all the dividers under test 330a-330n share a common serializer and/or common controller, and the Test output for multiple ones of the dividers 330a-330n is output to the common serializer and/or common test control block in parallel.

### Selection of NUM_TST_CLKS

While certain values of NUM_TST_CLKS have been described above for the purposes of illustration, different values of NUM_TST_CLKS can be selected for both 0->1 and 1->0 transition testing.

In general, selecting a high NUM_TST_CLKS value for testing can result in longer test times. Thus, it can be advantageous to select relatively lower NUM_TST_CLKS values. Depending on the embodiment, NUM_TST_CLKS can be selected to be less than 512, 256, 128, 64, 32, 16, or 8. In some embodiments, NUM_TST_CLKS is 1, resulting in very short test times. Thus, depending on the embodiment, NUM_TST_CLKS can be at least 2, 4, 8, 16, 32, 64, or 128. In certain implementations, NUM_TST_CLKS can be selected to be at least any of 2, 4, 8, 16, or 32 and less than any of 512, 256, 128, or 64.

### Exemplary Divider Circuit

FIG. 6 shows one example of a compatible analog divider circuit 600. For example, the divider circuit 600 may be used as the analog divider circuit 332 of the divider(s) under test 330a-330n of FIG. 3A, the analog divider circuit 324 of the interpolative divider 320 of FIG. 3A, the analog divider circuit 132 of the feedback divider 130 of FIG. 1, the analog divider circuit 124 of the interpolative divider 120 of FIG. 1, or as the analog divider circuits of any of the dividers 120 or 130a-130n of FIG. 2.

The illustrated analog divider circuit 600 forms an N-bit count-down divider including a series of sequentially connected flip-flops 602[0]-602[N−1] each having an output 604[0]-604[N−1] corresponding to a bit in the output of the divider circuit 600. The flip-flops 602[0]-602[N−1] can be complementary-metal oxide semiconductor (CMOS) devices, for example. The flip-flops 602[0]-602[N01] can be static or dynamic, and in some embodiments can implement charge steering circuitry. In some embodiments, the flip-flops 602[0]-602[N−1] can include both static and dynamic flip-flops, e.g., in a hybrid topology. Because the flip-flops 602[0]-602[N−1] reside in the analog domain and comprise analog and/or non-standard circuitry, the flip-flops 602[0]-602[N−1] may be generally incompatible with JTAG scan technology, the divider circuit according to certain embodiments does not include JTAG scan circuitry.

The input of each flip-flop 602[0]-602[N−1] of the count-down divider circuit 600 is connected to the output of a corresponding multiplexer 606[0]-606[N−1]. When load_div_code is asserted, each multiplexer 602[0]-602[N−1] is controlled to present a corresponding bit of div_code to the respective flip-flop 602[0]-602[N−1].

Each flip-flop can additionally include an asynchronous reset (RST) which receives a logical AND of LOAD_DIV_CODE and TM_LD_BYP. Thus, during test mode operation, TM_LD_BYP can be generally asserted throughout test mode, and assertion/deassertion of LOAD_DIV_CODE and RST will pre-load the divider circuit 600 via an asynchronous reset of each flip-flop 602[0]-602[N−1] to latch the corresponding div_code bit from the input of the flip-flop 602[0]-602[N−1] to the output of the flip-flop 602[0]-602[N−1].

The other input of each flip-flop 602[0]-602[N−1] is connected to an inverted version of the output of the flip-flop 602[0]-602[N−1]. Following pre-loading of the flip-flop 602[0]-602[N−1], LOAD_DIV_CODE is de-asserted, and each multiplexer 606a-606N-1 will present the inverted output to the input of the flip-flop 602[0]-602[N−1]. Subsequent pulsing of the test clock (GATED_ID_CLOCK) to the clock input of the flip-flip 602[0] for NUM_TST_CLKS clock cycles will result in the divider circuit 600 counting down from DIV_CODE by NUM_TST_CLKS.

The output 604[0]-604[N−1] of each flip-flop 602[0]-602[N−1] is connected the input of a corresponding buffer circuit 608[0]-608[N−1] or other appropriate circuitry, which has an output coupled to the input of a serializer, such as the serializer 336 of FIG. 3A. In this manner, a parallel read out of the count value is achieved for efficient testing purposes.

The output 604[0]-604[N−1] of each flip-flop 602[0]-602[N−1] is also connected to divider output logic circuitry 610. The divider output logic circuitry 610 can combine the output outputs of the flip-flops 604[0]-604[N−1] to generate a divided clock signal, e.g., during normal, non-test operation.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively.

While certain embodiments have been described, these embodiments have been presented by way of example only, and are not intended to limit the scope of the disclosure. Indeed, the methods, systems, and circuits described herein may be embodied in a variety of other forms. Furthermore, various omissions, substitutions, and changes in the form of the methods, systems, and circuits described herein may be made without departing from the spirit of the disclosure. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A timing circuit comprising:
an analog divider circuit including pre-load circuitry configured to allow for programming the analog divider circuit with a starting value, and responsive, synchronous with a divider clock, to count from the starting value, and the analog divider circuit further including an observation bus that outputs a current count value of the analog divider circuit; and
test clock logic configured, in a divider circuit test mode, to be responsive to a reference clock to output the divider clock to clock the analog divider circuit for a number of clock cycles corresponding to a programmable test clock length.

2. The timing circuit of claim 1 wherein the analog divider circuit forms a part of a phase-locked loop.

3. The timing circuit of claim 2 wherein the analog divider circuit is a feedback divider of the phase-locked loop.

4. The timing circuit of claim 2 wherein the analog divider circuit includes a plurality of series-connected flip-flops.

5. The timing circuit of claim 1 wherein the analog divider circuit includes count-down functionality.

6. The timing circuit of claim 5 wherein the analog divider circuit further includes count-up functionality.

7. The timing circuit of claim 1 wherein the test clock logic is further responsive to a test enable signal to output the divider clock.

8. The timing circuit of claim 7 wherein the analog divider circuit resides on an analog portion of a mixed-signal integrated circuit die, and the test enable signal is generated by a processing circuitry residing on a digital portion of the mixed-signal integrated circuit die.

9. The timing circuit of claim 1 wherein the reference clock is provided by a voltage controlled oscillator.

10. The timing circuit of claim 1 wherein the test clock logic resides in an interpolative divider.

11. A timing system comprising:
at least one timing circuit having a first divider circuit including pre-load circuitry configured to allow for programming the first divider circuit with a starting value, and the first divider circuit responsive, synchronous with a divider clock, to count from the starting value, and the first divider circuit further including an observation bus that outputs a current count value of the first divider circuit, the at least one timing circuit further including test clock logic configured, in a divider circuit test mode, to be responsive to a reference clock to output the divider clock to clock the first divider circuit for a number of clock cycles corresponding to a programmable test clock length.

12. The timing system of claim 11 wherein the at least one timing circuit further a second divider circuit, the timing system including control circuitry configured to control the first divider circuit to perform a first test routine and to control the second divider circuit to perform a second test routine at least partially in parallel with the first test routine.

13. The timing system of claim 12 wherein the control circuitry is further configured to read the current count value from the observation bus of the first divider circuit as a first test result of the first test routine and to read the current count value from the observation bus of the second divider circuit as a second test result of the second test routine.

14. The timing system of claim 13 wherein the observation bus of the first divider circuit outputs the first test result at least partially in parallel with the observation bus of the second divider circuit outputting the second test result.

15. The timing system of claim 13 wherein the first divider circuit and the second divider circuit each include a respective serializer circuit configured to serialize the first test result and the second test result.

16. The timing system of claim 11 wherein the first divider circuit forms a feedback divider of a phase-locked loop.

17. The timing system of claim 16 wherein the first divider circuit includes a plurality of series-connected flip-flops.

18. The timing system of claim 11 wherein the test clock logic is further responsive to a test enable signal to output the divider clock.

19. The timing system of claim 18 wherein the first divider circuit resides on an analog portion of a mixed-signal integrated circuit die, and the test enable signal is generated by a processing circuitry residing on a digital portion of the mixed-signal integrated circuit die.

20. A method of operating a timing circuit comprising:
programming an analog divider circuit of the timing circuit with a starting value using pre-load circuitry of the analog divider circuit;
counting, synchronous with a divider clock, from the starting value;
outputting with an observation bus of the analog divider circuit, a current count value of the analog divider circuit; and
with test clock logic of the timing circuit, in a divider circuit test mode and responsive to a reference clock, outputting the divider clock to clock the analog divider circuit for a number of clock cycles corresponding to a programmable test clock length.
